(19) United States
(12) Patent Application Publication
(10) Pub. No.: US 2025/0040221 A1
(43) Pub. Date: Jan. 30, 2025

(54) HIGH-ELECTRON-MOBILITY TRANSISTOR

(71) Applicant: GlobalFoundries U.S. Inc., Malta, NY (US)

(72) Inventors: Johnatan A. KANTAROVSKY, South Burlington, VT (US); Mark D. LEVY, Williston, VT (US); Alvin J. JOSEPH, Williston, VT (US); Santosh SHARMA, Austin, TX (US); Michael J. ZIERAK, Colchester, VT (US)

(21) Appl. No.: 18/226,982

(22) Filed: Jul. 27, 2023

(51) Int. Cl. H01L 29/40; H01L 29/20; H01L 29/423; H01L 29/66; H01L 29/778

(52) U.S. Cl. CPC H01L 29/404; H01L 29/2003; H01L 29/401; H01L 29/42316; H01L 29/66462; H01L 29/7786

(57) ABSTRACT

The present disclosure relates to semiconductor structures and, more particularly, to a high-electron-mobility transistor and methods of manufacture. The structure includes: a gate structure; a first field plate on a first side of the gate structure; and a second field plate on a second side of the gate structure, independent from the first field plate.

### BACKGROUND

The present disclosure relates to semiconductor structures and, more particularly, to a high-electron-mobility transistor and methods of manufacture.

A high-electron-mobility transistor (HEMT) is a field-effect transistor incorporating a junction between two materials with different band gaps as the channel instead of a doped region (as is generally the case for a MOSFET). A commonly used material combination is GaAs with AlGaAs, although there are other material variations dependent on the application of the device. HEMTs incorporating gallium nitride, for example, provide high-power performance.

HEMTs are able to operate at higher frequencies than ordinary transistors, up to millimeter wave frequencies. Accordingly, HEMTs are used in high-frequency products such as cell phones, satellite receivers, voltage converters, and radar equipment. The HEMT can also be used in low power applications such as low power amplifiers. HEMTs, though, can exhibit high gate to drain capacitance (Cgd), which can change with application of different voltages.

### SUMMARY

In an aspect of the disclosure, a structure comprises: a gate structure; a first field plate on a first side of the gate structure; and a second field plate on a second side of the gate structure, independent from the first field plate.

In an aspect of the disclosure, a gate structure comprises: a gate structure contacting a semiconductor material; a first field plate on a drain side of and electrically isolated from the gate structure; and a second field plate on a source side of and electrically isolated from the first field plate and the gate structure.

In an aspect of the disclosure, a method comprises: forming a gate structure; forming a first field plate on a first side of the gate structure; and forming a second field plate on a second side of the gate structure, independent from the first field plate.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1A shows a top view of the high-electron-mobility transistor (HEMT) structure and respective fabrication processes in accordance with aspect of the present disclosure.

FIG. 1B shows a cross-sectional view of the HEMT structure of FIG. 1A, along lines A-A.

FIGS. 2A-2G show respective fabrication processes for manufacturing a HEMT structure in accordance with aspect of the present disclosure.

### DETAILED DESCRIPTION

The present disclosure relates to semiconductor structures and, more particularly, to a high-electron-mobility transistor (HEMT) and methods of manufacture. More specifically, the HEMT includes self-aligned field plates under the gate structure. In embodiments, the field plates are positioned on opposing sides of the gate structure of the HEMT, in addition to being electrically isolated from each other and the gate structure. Advantageously, the HEMT described herein exhibits reduced gate-to-drain capacitance (Cgd) while minimizing the impact on gate-to-source capacitance (Cgs). The HEMT described herein also exhibits an increased Maximum Oscillation Frequency (Fmax) (e.g., by about 50%) with a small impact on Ft.

In more specific embodiments, the HEMT described herein may include two field plates adjacent the gate structure. For example, the field plates may be under a portion of the gate structure, arranged on opposite sides of the gate structure. The field plates may be electrically isolated from one another such that they can be independently biased with different electric potentials. Although not a limiting feature, the gate structure may be a “T” shaped structure, with the stem of the gate structure separating each of the field plates from one another.

The HEMT of the present disclosure can be manufactured in a number of ways using a number of different tools. In general, though, the methodologies and tools are used to form structures with dimensions in the micrometer and nanometer scale. The methodologies, i.e., technologies, employed to manufacture the HEMT of the present disclosure have been adopted from integrated circuit (IC) technology. For example, the structures are built on wafers and are realized in films of material patterned by photolithographic processes on the top of a wafer. In particular, the fabrication of the HEMT uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

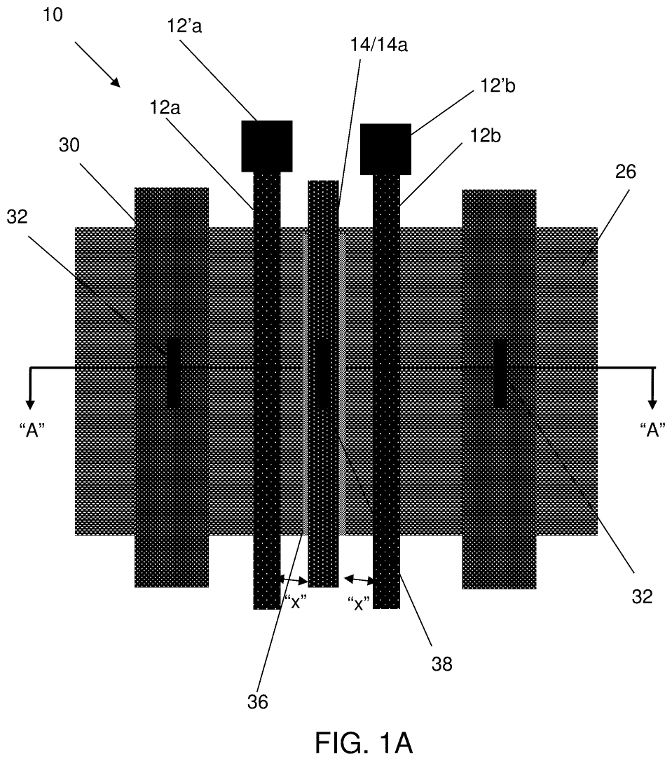

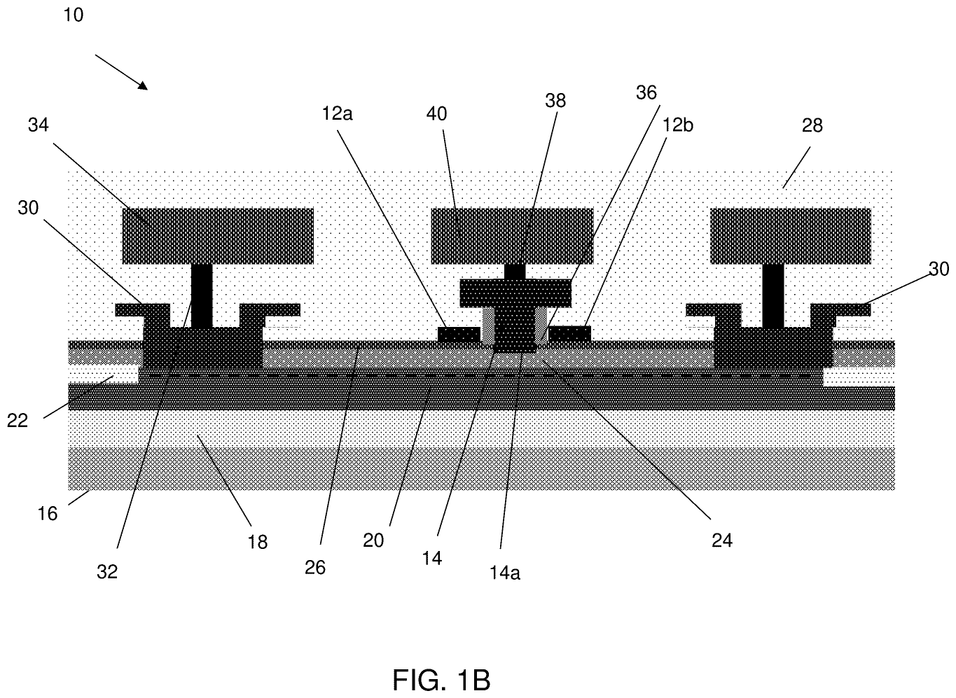

FIG. 1A shows a top view of the HEMT structure and respective fabrication processes in accordance with aspect of the present disclosure. FIG. 1B shows a cross-sectional view of the HEMT structure of FIG. 1A, along lines A-A. As shown in FIGS. 1A and 1B, the structure 10 includes field plates 12a, 12b electrically isolated from one another on opposing sides of a gate structure 14. In embodiments, the field plates 12a, 12b may be self-aligned field plates arranged on a source side and drain side, respectively, of the gate structure 14. The field plates 12a, 12b may also be separated from the gate structure 14 by a critical distance “x”. The field plates 12a, 12b may be symmetrically positioned on the sides of the gate structure 14. In embodiments, the stem of the gate structure 14 (e.g., gate stem 14a shown in FIGS. 1A and 1B) separates or divides the parts of the field plate 12a, 12b across the finger width (even outside the active region).

As should be understood by those of skill in the art, the field plates 12a, 12b can reduce the overall capacitance of the HEMT. In addition, by having the field plates 12a, 12b electrically isolated from one another, it is now possible to provide a separate, independently controlled voltage potential to the field plate 12a. And, by providing a potential independently to the field plate 12a on the source side, it is now possible to reduce Cgd. In embodiments, the potentials provided to the field plates 12a, 12b are shown in example Table 1 below.

TABLE 1

| | Potential to Source Contact | Potential to Drain Contact |
|---|---|---|
| | (field plate 12a on source) | (field plate 12b on drain) |
| 1 | Grounded | Floating or grounded or |
| | | external voltage source |
| 2 | Floating | Floating or grounded or |
| | | external voltage source |
| 3 | Gate | Floating or grounded or |
| | | external voltage source |
| 4 | Drain | Floating or grounded or |
| | | external voltage source |
| 5 | External voltage | Floating or grounded or |
| | source | external voltage source |

By way of an example improvement, simulations show that Fmax can be improved by about 50% when the field plate 12a is floating. In addition, when both of the field plates 12a, 12b are grounded, simulations show that Fmax can increase by about 43%. In addition, in the case the field plate 12a is floating and the field plate 12b is grounded, simulations show that Cgd decreases by about 60% and Cgs increases by about 34%. Moreover, in the case when both the field plates 12a, 12b are grounded, simulations show that Cgd decreases by about 60% and Cgs increases by about 49%.

More specifically and referring to FIGS. 1A and 1B, the structure 10 comprises a semiconductor substrate 16. In embodiments, the semiconductor substrate 16 may be a handle substrate comprising any suitable material including, but not limited to, Si, SiGe, SiGeC, SiC, GE alloys, GaAs, InAs, InP, and other III/V or II/VI compound semiconductors. A buffer layer 18 may be formed on the semiconductor substrate 16. In embodiments, the buffer layer 18 may be Si or SiC or other material which helps to reduce a lattice mismatch between the semiconductor substrate 16 and a semiconductor layer 20 on the buffer layer 18. By way of illustrative, non-limiting example, the semiconductor layer 20 may be GaN.

The semiconductor layer 20 exhibits 2 deg as shown by the dashed lines between the isolation structures 22. It should be understood by those of skill in the art that 2 deg refers to a two-dimensional electron gas, which is a scientific model in solid-state physics referring to an electron gas that is free to move in two dimensions, but tightly confined in the third dimension. Thus, the electrons appear to be a 2D sheet embedded in a 3D environment.

Still referring to FIG. 1B, isolation structures 22 may be provided within the semiconductor layer 20. In embodiments, the isolation structures 22 may be shallow trench isolation structures composed of SiO₂, for example. The isolation structures 22 can be formed by conventional lithography, etching and deposition methods known to those of skill in the art. For example, a resist formed over the semiconductor layer 20 is exposed to energy (light) and developed utilizing a conventional resist developer to form a pattern (opening). An etching process with a selective chemistry, e.g., reactive ion etching (RIE), will be used to transfer the pattern from the resist layer to semiconductor layer 20 to form one or more trenches in the semiconductor layer 20 through the openings of the resist. Following the resist removal by a conventional oxygen ashing process or other known stripants, insulator material can be deposited by any conventional deposition processes, e.g., chemical vapor deposition (CVD) processes. Any residual material on the surface of the semiconductor layer 20 can be removed by conventional chemical mechanical polishing (CMP) processes.

FIG. 1B further shows a barrier layer 24 and a passivation layer 26 on the semiconductor layer 20. In embodiments, the barrier layer 24 may be AlGaN, as an example, and the passivation layer 26 may be SiN, as an example. In embodiments, the barrier layer 24 and the passivation layer 26 may be deposited by a conventional deposition method, e.g., CVD. An interlevel dielectric material 28 may be formed over the passivation layer 26. The interlevel dielectric material 28 may comprise, for example, alternating layers of SiN and SiO₂ as is known in the art. The interlevel dielectric material 28 may also be deposited by a conventional deposition method, e.g., CVD.

Ohmic contacts 30 may be formed in electrical contact to the semiconductor layer 20, extending and contacting to a source region and drain region of the HEMT. In embodiments, the ohmic contacts 30 may be composed of any metal or metal alloy material as is known in the art, such as, e.g., TiN or copper. A via contact 32 and wiring structure 24 may be formed to the ohmic contacts 30 for both the source region and the drain region. In embodiments, the ohmic contacts 30, via contacts 32 and wiring structures 24 may be formed by conventional lithography, etching and deposition processes as is known in the art. By way of example, the via contacts 32 and wiring structures 24 may be formed by a dual damascene process or separate single damascene processes as is known in the art such that no further explanation is required for a complete understanding of the present disclosure.

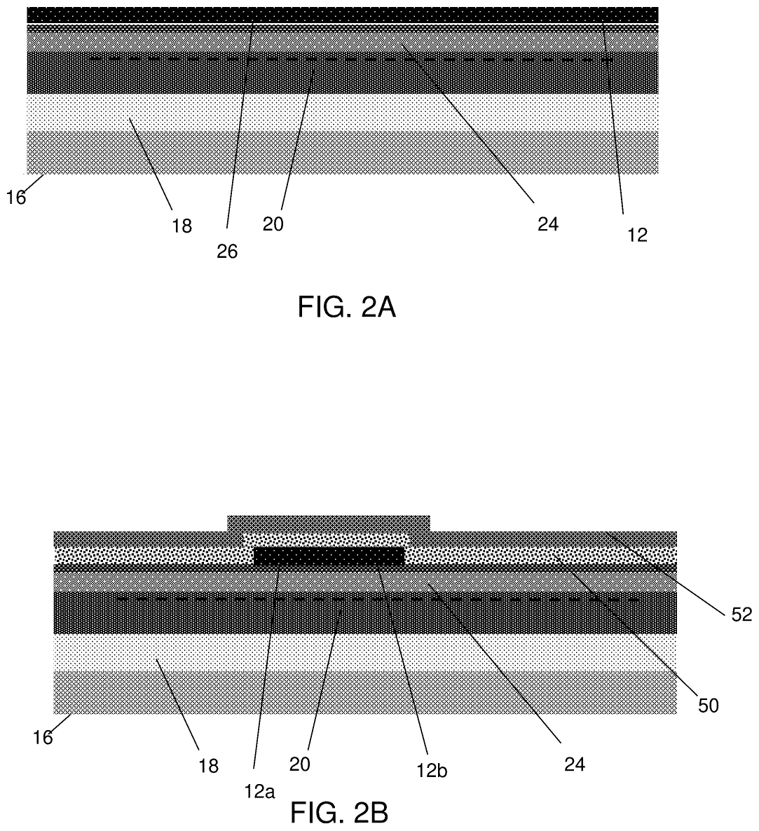

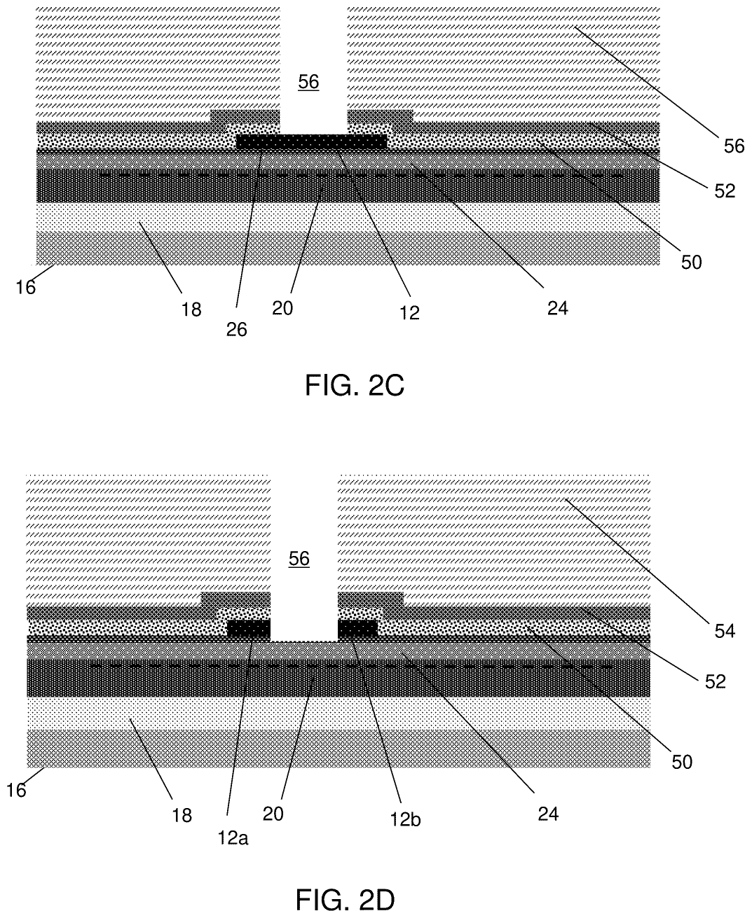

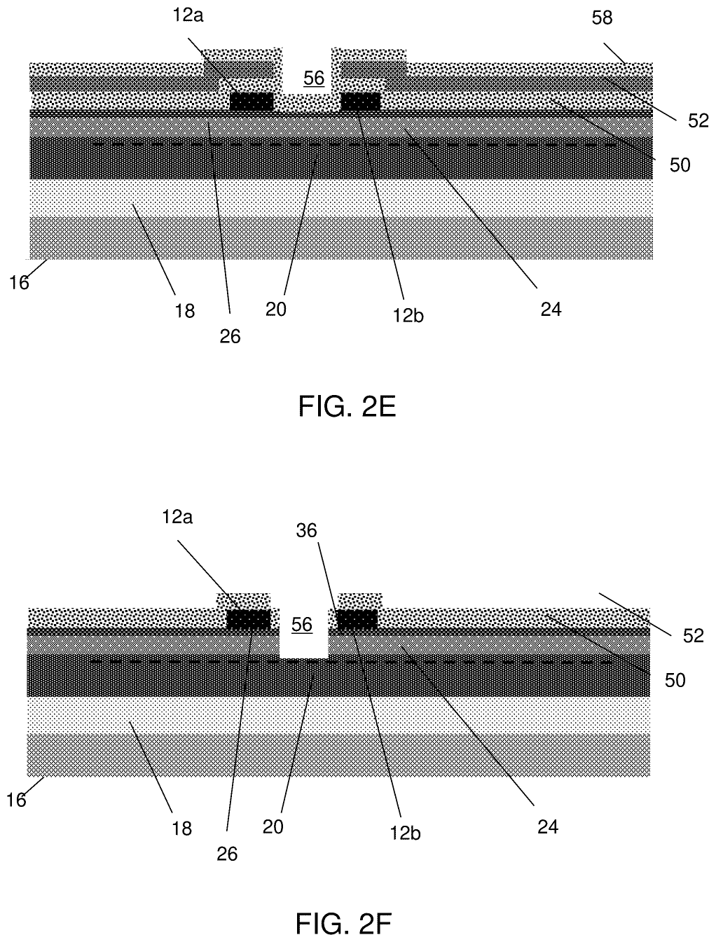

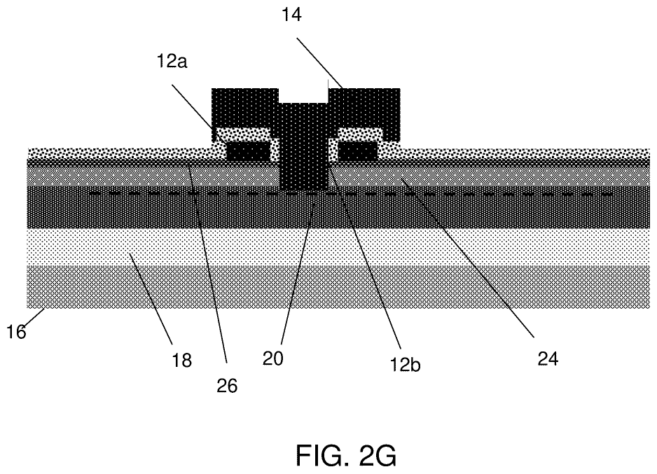

FIGS. 1A and 1B further show the field plates 12a, 12b on opposing sides of the gate structure 14. In embodiments, the field plates 12a, 12b may be symmetrically positioned about the gate structure 14 and electrically isolated from one another and from the gate structure 14. The field plates 12a, 12b may be separated from the gate structure 14 by sidewall spacers 36. As described in FIGS. 2A-2G, the field plates 12a, 12b may be self-aligned field plates with a critical dimension (CD) “x” between the field plates 12a, 12b and the gate structure 14. The sidewall spacers 36 may be nitride or oxide based materials.

In embodiments, the field plate 12a may be formed on the source side of the gate structure 14; whereas the field plate 12b may be formed on the drain side of the gate structure 14. As seen in FIG. 1A, for example, the field plates 12a, 12b may be electrically isolated from one another such that a separate voltage potential can be applied independently to each of the field plates 12a, 12b as shown and described with respect to Table 1. In this way, the field plate 12a on the source side is independent of the field plate 12b on the drain side of the gate structure such that a different potential may applied to each of the contacts 12′a, 12′b of the respective field plates 12a, 12b.

The field plates 12a, 12b are formed on the passivation layer 26. The field plates 12a, 12b may be formed from the same or different conductive material as the gate structure 14. For example, the gate structure 14 may be formed from known workfunction metals such as, e.g., Ti, TiAlC, Al, TiAl, TaN, TaAlC, TiC, TaC, Al, HfTi, TiSi, TaSi and Co. Also, in embodiments, the gate structure 14 may be T-shaped, with the field plates 12a, 12b being located under the horizontal section of the T-shape. In embodiments, the gate structure 14 may extend further than the field plates 12a, 12b in a longitudinal direction; although other configurations are also contemplated herein. Moreover, the gate structure 14 may be other shapes such as a vertical structure with straight sidewalls.

Although not critical to the understanding of the present disclosure, the gate structure 14 can be fabricated using conventional CMOS processes, prior to the deposition of the interlevel dielectric material 28. In the CMOS processing, a trench may be formed in the passivation layer 26 to expose the underlying barrier layer 24. In embodiments, the trench may also extend into the barrier layer 24. A gate metal material (e.g., workfunction materials) may be deposited within the trench and over the passivation layer 26. The gate metal material may be formed by CVD, physical vapor deposition (PVD) including sputtering, atomic layer deposition (ALD) or other suitable method. The gate metal material can be patterned using conventional lithography and etching processes as is known in the art such that no further explanation is required for a complete understanding of the present disclosure. The sidewall wall material may also be deposited on sidewalls of the trench and/or gate metal material. The via contacts 38 and wiring structures 40 may be electrically formed to the gate structure 14 using conventional lithography, etching and deposition methods, subsequent to the deposition of the interlevel dielectric material 28.

FIGS. 2A-2G show respective fabrication processes for manufacturing a HEMT structure in accordance with aspect of the present disclosure. For example, FIG. 2A shows a layered structure comprising the semiconductor substrate 16, buffer layer 18, semiconductor layer 20, barrier layer 24, passivation layer 26 and a metal layer 12. In embodiments, the buffer layer 18, semiconductor layer 20, barrier layer 24, passivation layer 26 and a metal layer 12 may be formed by any conventional deposition process such as, e.g., CVD or PECVD.

In FIG. 2B, the metal layer 12 may be patterned to form a single plate. In embodiments, the metal layer 12 may be patterned by a conventional lithography and etching process as is known in the art. For example, a resist formed over the metal layer 12 is exposed to energy (light) and developed utilizing a conventional resist developer to form a pattern (opening). An etching process with a selective chemistry, e.g., RIE, will be used to transfer the pattern from the patterned photoresist layer to the metal layer 12.

Still referring to FIG. 2B, an oxide material 50 and a hardmask 52, e.g., sacrificial SiN material, may be deposited on the patterned metal layer 12. In embodiments, the oxide material 50 and hardmask 52 may be deposited by a CVD process, as an example. In embodiments, the oxide material 50 may be thicker than the hardmask 52.

In FIG. 2C, a resist 54 is formed over the hardmask 52. An etching process is performed to form a stem opening 56 into the oxide material 50 and hardmask 52. In this way, the patterned metal layer 12 is exposed.

In FIG. 2D, the metal layer 12 is also etched to form two plates, e.g., field plate 12a, 12b. The metal layer 12 may be etched by conventional etching processes, with a chemistry that is selective to the metal layer 12. In this way, the field plates 12a, 12b are on a same level, made of a same metal material, and are planar with one another.

In FIG. 2E, the resist can be removed by a conventional process, e.g., oxygen ashing or other stripant. An insulator material 58 may be deposited on the hardmask 52 and with the opening 56, including on sidewalk of the field plates 12a, 12b. In embodiments, the insulator material 58 may be deposited by a CVD process, as an example. The insulator material may be oxide, for example.

In FIG. 2F, the insulator material 58 is removed from a bottom surface of the opening 56 and on the upper surface of the hardmask 52. This will leave sidewall spacers 36 on the ends of the field plates 12a, 12b. In addition, the hardmask, e.g., sacrificial SiN material, can be removed by a conventional etching process. In embodiments, the etching process will also etch through the AlGaN material, e.g., barrier layer 24, to expose the semiconductor layer 20.

In FIG. 2G, a metal material, e.g., gate metal, can be deposited on the oxide material 50, within the opening, and contacting the semiconductor layer 20. The metal material 14a can be patterned to form the gate structure 14. In embodiments, the gate structure 14 can be patterned by a conventional lithography and etching, e.g., RIE, as already described herein.

Referring back to FIG. 1B, the via contacts 38 and wiring structures 40 may be electrically formed to the gate structure 14 using conventional lithography, etching and deposition methods, subsequent to the deposition of the interlevel dielectric material 28. The via contact 32 and wiring structure 24 may also be formed to the ohmic contacts 30 for both the source region and the drain region by conventional lithography, etching and deposition processes as is known in the art.

The HEMT can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a gate structure;
a first field plate on a first side of the gate structure; and
a second field plate on a second side of the gate structure, independent from the first field plate.

2. The structure of claim 1, wherein the first field plate is electrically isolated from the second field plate.

3. The structure of claim 2, wherein the first field plate and the second field plate are electrically isolated from the gate structure.

4. The structure of claim 3, wherein the first field plate and the second field plate are under a portion of the gate structure.

5. The structure of claim 1, wherein the first field plate and the second field plate comprise a same metal material and are planar with each other.

6. The structure of claim 1, wherein the gate structure comprises sidewall spacers which isolate the first field plate and the second field plate from the gate structure.

7. The structure of claim 1, wherein the first field plate is on a source side of the gate structure and the second field plate is on a drain side of the gate structure.

8. The structure of claim 7, wherein the first field plate and the second field plate have independently controlled voltage potentials.

9. The structure of claim 1, wherein the first field plate and the second field plate are symmetrically positioned about the gate structure.

10. The structure of claim 1, wherein the gate structure comprises a T-shape and the first field plate and the second field plate are under a horizontal portion of the T-shape gate structure.

11. The structure of claim 10, wherein the horizontal portion of the T-shape gate structure extends further than the first field plate and the second field plate.

12. The structure of claim 1, wherein the gate structure comprises a high-electron-mobility transistor contacting a semiconductor material.

13. The structure of claim 12, wherein the first field plate and the second field plate are on an insulator material above the semiconductor material.

14. A structure comprising:
a gate structure;
a first field plate on a drain side of and electrically isolated from the gate structure; and
a second field plate on a source side of and electrically isolated from the first field plate and the gate structure.

15. The structure of claim 14, wherein the gate structure comprises a high-electron-mobility transistor contacting a semiconductor material.

16. The structure of claim 14, wherein the first field plate and the second field plate are symmetrically positioned about the gate structure.

17. The structure of claim 14, wherein the first field plate and the second field plate are on a same level.

18. The structure of claim 17, wherein the first field plate and the second field plate are planar and made of a same material.

19. The structure of claim 14, wherein the first field plate and the second field plate have independently controlled potentials.

20. A method comprising:
forming a gate structure;
forming a first field plate on a first side of the gate structure; and
forming a second field plate on a second side of the gate structure, independent from the first field plate.
